(19) United States
(12) Patent Application Publication
(10) Pub. No.: US 2020/0052460 A1
(43) Pub. Date: Feb. 13, 2020

(54) OPTICAL MODULE

(71) Applicant: OPTELLA INC., Gwangiu (KR)

(72) Inventors: Sang Soo LEE, Daejeon (KR); Jyung Chan LEE, Daejeon (KR); Eun Gu LEE, Daejeon (KR)

(21) Appl. No.: 16/342,966

(22) PCT Filed: Jan. 19, 2017
(86) PCT No.: PCT/KR2017/000653

§ 371 Date: Apr. 17, 2019

(30) Foreign Application Priority Data
Oct. 18, 2016 (KR) 10-2016-0134942

(51) Int. Cl. H01S 5/022; G02B 7/02

(52) U.S. Cl. CPC H01S 5/02252; G02B 7/022; H01S 5/0226; H01S 5/02276

(57) ABSTRACT

Disclosed is an optical module, including a mount, a laser diode driver and a sub-mount installed on the mount, a plurality of laser diodes disposed on the sub-mount, an electrical signal interface disposed on the mount, and a circuit connecting the electrical signal interface and signal input/output terminals of the laser diode driver and connecting the signal input/output terminals of the laser diode driver to the laser diodes through a terminal of the sub-mount. The front of the laser diode is inward recessed at a specific distance from the front of the sub-mount and thus stepwise disposed with respect to an optical signal interface including the front of the sub-mount. A front groove is formed in the direction in which a laser travels at a location that belongs to a surface of the sub-mount to which the bottom of the laser diode is attached and that corresponds to a forward path in which the laser is forward emitted from the front of the laser diode. In accordance with the present invention, the plurality of lasers is disposed close to a single package to form a structure not using a lens array, but forms a simplication, small-size and integration package type structure. Accordingly, a production cost can be reduced and an adverse influence on the edge of the mount when the optical signal interface has a step with respect to the side of the mount in order to protect the laser diode can be prevented.

### TECHNICAL FIELD

The present invention relates to an optical module and, more particularly, to an optical module capable of receiving an electrical signal and outputting an optical signal or receiving an optical signal and outputting an electrical signal or a transmission/reception optic sub-assembly for optical communication.

### BACKGROUND OF THE INVENTION

A scheme for increasing a capacity for data traffic continues to be researched due to the enlargement of services based on a large amount of content, a sudden increase of the supply of smart phones and a sharp increase of data centers. In order to solve such a scheme, an international standardization organization related to communication has issued standard proposals using the same wavelength multi-channel technology and a wavelength division multiplexing technology, and many institutes and researchers are researching methods for implementing such technologies. Such standards and technologies need to solve lower price, higher speed, smaller size and lower power issues. An optical transmitter based on a laser array is being developed as an overcoming scheme in terms of an optical transceiver, that is, an element forming a network, and the optical transmitter is practically used in the application fields.

In the optical transmitter, in general, a lens is used to improve optical coupling efficiency between a laser and an optical waveguide. If optical coupling is implemented using the lens optical coupling efficiency can be improved or a tolerance can be increased depending on the characteristics of a system or an optimized package structure can be designed in a proper level between the laser and the optical waveguide. If the interval between lasers is made 250 um for optical coupling between an existing optical fiber array and an optical waveguide array, however, lenses used for optical coupling have an array form. Accordingly, there is a disadvantage in that a cost rises. If a laser installation pitch is increased in order to reduce a production cost of the lens array, the price of the laser rises because the number of lasers capable of being fabricated in a single wafer is reduced.

An existing optical engine uses two lenses or one lens because it basically uses a 45-degree mirror and thus the distance between a light source (or a photo sensor) and an optical waveguide (optical fiber) is distant. In this case, there are disadvantages in that a structure is complicated and a packaging process is difficult because many devices, such as a guide post and a latch, are inserted for optical coupling. Furthermore, most of the existing optical engines are not suitable for being used in a system using a multi-wavelength because they use an optical waveguide array not using an optical multiplexer (optical wide multiplexer).

If a plurality of lasers is formed in a single chip, it becomes difficult to use in a standard using four wavelengths having a wide wavelength interval, such as 40G BASE-LR4 or 100G BASELR4. The reason why it is difficult to make different wavelengths if a plurality of lasers is configured in a single chip is as follows. First, a wide gain curve needs to be obtained because a plurality of lasers uses the same active layer, but it is difficult to satisfy such a condition upon growth. Second, a laser has a different oscillating wavelength depending on the length of a resonator. If a plurality of lasers is configured in a single chip, it is difficult to make different the length of the resonator. A laser may be made to operate in a relatively wide range in a single chip. However, it is difficult to handle current increasing traffic because there is a disadvantage in that a production cost increases.

In order to output different wavelengths, a method for implementing a laser array by mounting independent lasers on a single mount may be used. In this case, a cheap lens array having a relatively long distance between the lenses can be used because the interval between the lasers can be widened without a reduction in the number of lasers per wafer and the interval between lens arrays can also be widened. However, if an existing package method is used although a cheap lens array is used, there are still disadvantages in terms of parts used in the package, a packaging time and a packing cost.

For example, in the case of an optical transmitter operating at high speed, in order to guarantee a high-speed electrical interface and high reliability, a package of a mini DIL form using ceramic-feed through is used. In this case, the price of a casing used as a part is high, and the packaging time is increased because a work is performed in a narrow space within the casing. Accordingly, there is a disadvantage in that the price of an optic sub-assembly (OSA) itself rises.

The fundamental reason why such problems occur stems from a contradictory situation in that an optical transceiver connecting physical layers requires high performance in terms of operation due to suddenly increasing data traffic, whereas the size of a part forming a network needs to be reduced in terms of management and the price needs to be lowered due to the problem of an equipment cost.

In order to solve such problems of an existing technology situation and the contradiction, there is a need for a high speed, integration/high performance and cheap optical module. An optic sub-assembly for optical communication transmission/reception of a package form for such a module may be preferred, if any.

### PRIOR ART DOCUMENT

### Patent Document

(Patent Document 1) Korean Patent Application No. 10-2015-0165544: Optical module and optical engine including the same

(Patent Document 2) U.S. Patent Application Publication No. 2004/0264884: Compact package design for vertical cavity surface emitting laser array to optical fiber cable connection

(Patent Document 3) U.S. Patent Application Publication No. 2006/0162104: High speed optical sub-assembly with ceramic carrier.

### CONTENTS OF THE INVENTION

### Problems to be Solved by the Invention

The present invention has been made to solve the problems of the existing technology, and an object of the present invention is to provide a package type optical module of a simple structure, which is capable of solving a problem in that a laser array operating in a single wavelength is used for compatibility with an optical waveguide array and a problem in that a lens array is used by forming a plurality of lasers operating in different wavelengths in an array form in order to use a multi-wavelength.

In accordance with an aspect of the present invention, an object of the present invention is to provide the additional structure of a mount, wherein light emitted forward from the front of a plurality of laser diodes of a stem is not hindered by a sub-mount in which a laser diode has been disposed if a package type optical module has been formed and whether a laser is emitted to the back of the laser diode can be checked.

### Means for Solving the Problems

An optical module of the present invention for achieving the above objects includes a mount, a laser diode (LD) driver and a sub-mount installed on the mount, a plurality of laser diodes disposed on the sub-mount, an electrical signal interface disposed on the mount, and a circuit connecting the electrical signal interface and signal input/output terminals of the LD driver and connecting the signal input/output terminals of the LD driver to the laser diodes through a terminal of the sub-mount, wherein the front of the laser diode is inward recessed at a specific distance from the front of the sub-mount and stepwise disposed with respect to the front of the sub-mount, and a front groove that prevents hindrance to the travel (scattering, refraction, reflection, etc.) of laser light is formed at a portion that belongs to a surface of the sub-mount and that includes the edge of the sub-mount in the direction in which the laser light emitted from the front of the laser diode travels.

The front of the sub-mount may be aligned with respect to the front of the mount to form the interface surface of an optical signal interface. More specifically, the front groove includes the edge portion of the sub-mount in the path in which the laser is emitted, and may be a groove of a specific depth or a groove having a depth gradually deepened from the front of the laser diode to the edge of the sub-mount.

In the present invention, a concave groove or hole is formed in the sub-mount in the periphery of the back of the laser diode, and prevents that laser light emitted from the back is incident on the laser diode again by hindering the travel (scattering, refraction, reflection, etc.) of the laser light. Furthermore, the groove or hole formed in the periphery of the back may be designed so that the path of the output laser light is directed toward the input unit of a photo sensor, so forward output light power of the laser diode may be calculated.

In the present invention, an installation groove of a specific depth may be formed in an area that belongs to the surface of the sub-mount and to which the bottom of the laser diode is attached. The front groove (front tunnel) may be formed from the installation groove to the front of the mount that forms the optical signal interface. Furthermore, a bonding substance may have been already formed in the area that belongs to the surface of the sub-mount and to which the bottom of the laser diode is attached in order to facilitate the adhesion of the laser diode and the sub-mount.

In the present invention, the electrical signal interface may mean a contract surface where electrical signals are exchanged with other elements, and may be considered to be a concept including an electrical pad and a via. The electrical signal interface may include an electrical digital signal interface and an electrical analog signal interface.

In the present invention, an electrical circuit board (ECB) capable of configuring a three-dimensional circuit may be used as the mount. The ECB has an insulating property for an independent operation between the electrical pad and the via. Furthermore, the ECB may be an ECB capable of forming an electrical pad and a via in one or more planes for a high-speed signal transfer characteristic, a heat transfer characteristic and easy fabrication.

For example, for the heat transfer characteristic, the mount may include the electrical circuit board (ECB) having an insulation property and including at least one pad for heat transfer to at least one plane of the mount. In this case, as a heating element or other heaters disposed on the mount may be provided so that a bottom surface thereof thermally contacts the pad for heat transfer, heat may be discharged to the external electrical circuit board, which is separated from the optical module, or the heat sink, to which the optical module is attached, through a via (thermal via) thermally contacting the pad and passing through the mount (electrical circuit board) and at least one pad thermally contacting the via and provided on a bottom surface of the mount. Here, in a broad sense, the pad, which is disposed on the at least one plane of the mount or a bottom surface of the mount, may be an exposed upper end or an exposed lower end of the via instead of being provided separately from the via (thermal via), and the via may play the role of a passage of an electrical signal (electrical via) as well as a simple thermal passage. Thus, the via may be used as a ground (ground connection) passage for improving a high speed signal characteristic in the entire circuit as a kind of electrical via. To properly play the role of the thermal via or the electrical via, the via may be preferred to be made of a material having excellent thermal and electrical conductivity.

If the electrical circuit board is used as the mount, the via of the digital signal interface may include a via formed to penetrate a thin portion including only the base layer of the circuit board. The via of the analog signal interface may include a via formed in a thick portion including the base layer and cover layer of the circuit board. In this case, the LD driver chip and the sub-mount may have been disposed in the thick portion of the circuit board.

### Effects of the Invention

In accordance with the present invention, a problem in that a plurality of lenses or a lens array is used can be solved by installing a plurality of lasers, operating in different wavelengths, close to a single package in order to use a multi-wavelength.

Furthermore, in a system using the same wavelength (within a standard and commercial tolerance range) as a multi-channel, although it is difficult to use a laser array (i.e., a multi-channel laser formed of one chip) due to low yield, one laser (or a plurality of laser arrays) can be made to be used in an array form without using a plurality of lenses or a lens array.

Furthermore, although the yield of a laser array is commercially tolerant, the present invention has advantages in that the process time and the degree of difficulty are reduced because flip chip bonding is possible and thus a packaging cost is reduced.

Accordingly, in the present invention, in forming a laser of a single chip form in an array form (a plurality of lasers or a plurality of laser arrays), an overall structure is simple, a flip chip bonding process is possible and a plurality of lenses or a lens array does not need to be used. Accordingly, a small size and integration package type structure is possible and there is an enough room to reduce a production cost.

In accordance with the present invention, although a package type optical module is formed and light forward emitted from the front of a plurality of laser diodes is configured stepwise respect to the front of a sub-mount in order to protect the front of the laser diodes, laser light emitted by the laser diodes may not be unreasonably influenced by a surface of an adjacent sub-mount and a substance attached to the surface of the adjacent sub-mount because the front groove (front tunnel) is formed.

### BRIEF DESCRIPTION OF THE DRAWINGS

FIG. 1 is a configuration concept view schematically showing a configuration according to an embodiment of the present invention using a box diagram,

FIG. 2 is a schematic perspective view showing an embodiment of the present invention,

FIG. 3 is a schematic front sectional view showing a front cross section according to an embodiment of the present invention,

FIG. 4 is an exploded perspective view showing a sub-mount and laser diode coupling unit according to an embodiment of the present invention, and

FIGS. 5 and 6 are schematic perspective views showing an example of the configuration of an optical engine configured using an embodiment of the present invention and are diagrams showing an optical module and a waveguide block in an isolation state.

### DETAILED DESCRIPTION FOR IMPLEMENTING THE INVENTION

Hereinafter, the present invention is described in more detail through embodiments with reference to the accompanying drawings.

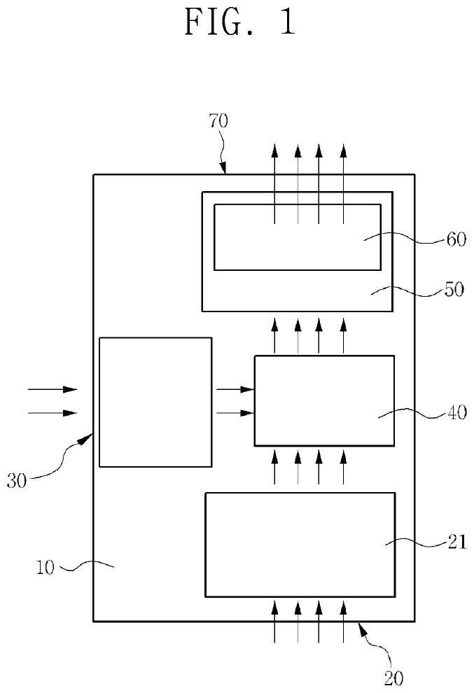

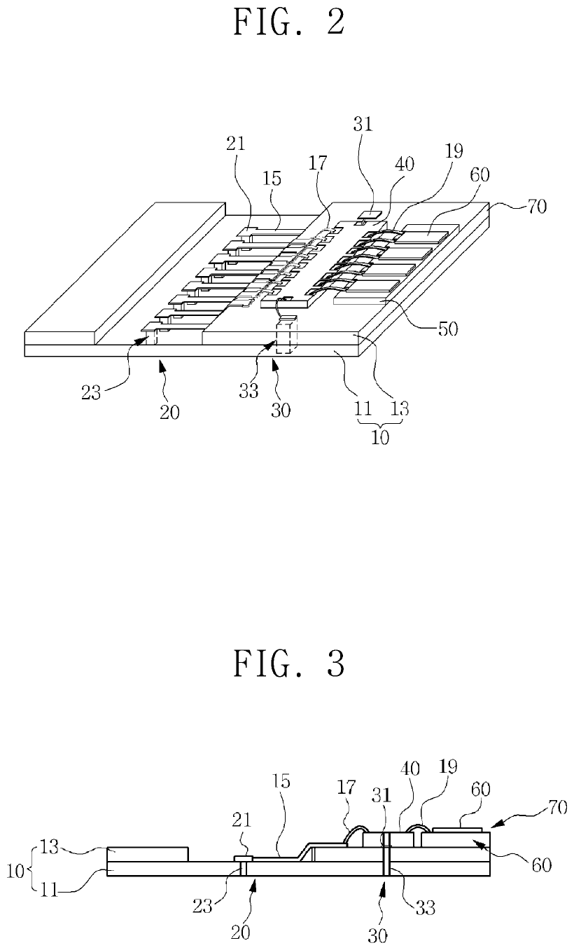

Referring to FIGS. 1 to 3, an optical module of the present embodiment is configured in an integration type package form, including a circuit board 10, a laser diode (LD) driver chip 40 disposed on the circuit board, a sub-mount 50 on which a plurality of laser diodes 60 is disposed, the plurality of laser diodes 60 disposed on the sub-mount, an electrical signal interface (a concept including an electrical signal terminal and a via) prepared in the circuit board 10, and a circuit (conducting wire) that connects the electrical signal interface and the signal terminals of the LD driver chip 40 and connecting the signal terminals of the LD driver chip 40 to the laser diodes 60 through the terminals of the sub-mount 50.

In this case, the laser diode 60 adopts a laser diode that emits laser light from its front side and also emits some backward laser light weaker than the front laser light.

The front of the circuit board 10 and the front of the sub-mount 50 are aligned to form fronts that are consecutive in a package, and they form an optical signal interface 70. In this case, the front of the laser diodes is inward recessed at a specific distance from the front of the sub-mount. As a result, the front of the laser diodes is stepwise disposed with respect to a surface of the optical signal interface 70 including the front of the sub-mount.

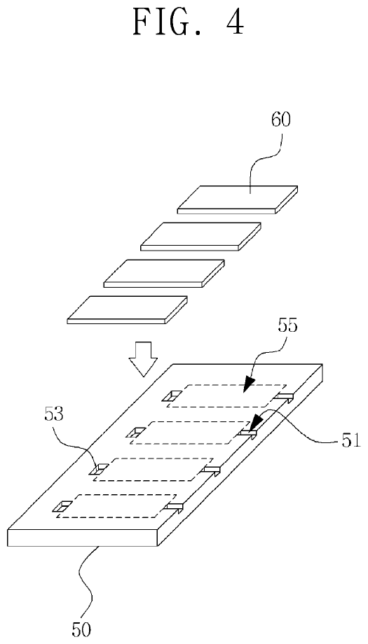

Furthermore, as disclosed in FIG. 4, a front groove 51 is formed in the direction in which a laser travels at a location that belongs to a surface of the sub-mount to which the bottom of the laser diode is attached and that corresponds to a forward path in which the laser is forward emitted from the front of the laser diode. In this case, more specifically, the front groove 51 is formed in a specific depth and width from the front of the laser diode 60 to the edge portion of the sub-mount 50 in the path in which the laser is emitted. In another embodiment, the front groove does not have a specific depth, but may be a groove having a depth gradually deeper from the front of the laser diode 60 to the edge of the sub-mount 50.

The front groove 51 can reduce a problem in that optical performance is deteriorated by preventing hindrance to the travel (scattering, refraction, reflection, etc.) of laser light emitted from the front of the laser diode. For example, the front groove 51 can reduce a problem in that optical efficiency is deteriorated because the amount of light inputted to a waveguide plate neighboring an optical signal interface is reduced due to the hindrance of the sub-mount or adhesives or the amount of light inputted to the waveguide plate generates noise without being propagated although the light is inputted to the waveguide plate by preventing the hindrance.

Furthermore, if adhesives are used when the laser diode 60 is attached to the sub-mount 50, the front groove 51 functions to provide a space into which the adhesives flow although the adhesives stick out from an attachment area. As a result, the front groove 51 can function to prevent a problem in that laser light emitted from the front of the laser diode 60 is hindered because the adhesives stick out from the attachment area and adhere to the front of the laser diode 60.

Meanwhile, a concave groove 53 or a hole is formed in the sub-mount 50 in the periphery of the back of the laser diode 60, and a photo sensor (photo detector, not shown) is disposed within the groove 53. When the intensity of laser light emitted from the back of the laser diode exceeds a specific value, the photo sensor detects such light and sends a signal to the outside through a signal line connected to the photo sensor so that the user of the optical module can recognize the problem. Furthermore, the concave groove 53 or the hole formed in the sub-mount in the periphery of the back of the laser diode 60 functions to prevent hindrance to the travel of laser light and also to prevent a change in the boundary condition at an output boundary surface at the back of the laser diode.

In some embodiments, an installation groove of a specific depth may be disposed in an area 55 that belongs to a surface of the sub-mount 50 and that to which the bottom of the laser diode is attached. In this case, a flat installation surface is used in the area. In the installation surface, when the laser diode is disposed on the sub-mount, the laser diode 60 can be moved in every direction in order to install the laser diode at its regular position. In an embodiment, there is no problem in that a movement of the laser diode 60 is hindered because the photo sensor is not disposed on the surface of the sub-mount 50, but is buried in the hole or the groove 53.

In the present embodiment, in general, the electrical signal interface means a contract surface or interface surface, that is, a portion at which electrical signals are exchanged with other parts with which the electrical signals are exchanged, but is connected to an electrical terminal exposed to the interface surface and used as a meaning that includes vias 23 and 33 penetrating the circuit board and electrical terminals 21 and 31 on a surface on the other side of the interface surface.

In this case, the interface surface is the bottom of the circuit board 10, part of the bottom of the circuit board forms an electrical digital signal interface 20, and the other part of the bottom of the circuit board forms an electrical analog signal interface 30. In this case, the via 23 of the digital signal interface includes a via formed to penetrate a thin portion including only the base layer 11 (bottom layer) of the circuit board. The via 33 of the analog signal interface includes a via formed in a thick portion including the base layer 11 and cover layer 13 of the circuit board.

The LD driver chip 40 and the sub-mount 50 are disposed in parallel in the thick portion of the circuit board 10 in the state in which the electrical terminals of the LD driver chip 40 and the sub-mount 50 are upward directed. An electrical circuit board (ECB) is used as the circuit board 10. In this case, although not shown, electrical terminals or electrical pads connected to the vias are formed at the bottom of the electronic circuit. Other parts for exchanging digital electrical signals and other parts for exchanging analog electrical signals are disposed at the bottom of the ECB for electrical connection with the pads.

Other parts may play the role of heat sink for removing heat generated from the circuits of a flexible printed circuit board.

For example, when the mount includes the electrical circuit board (ECB) having an insulation property as described in this embodiment, as at least one surface pad for heat transfer to at least one plane of a plurality of layers of the mount is installed, a bottom surface of the heater, such as the driver circuit and the sub-mount for the laser diode disposed on the mount, is disposed on the surface pad for thermal contact, the via (thermal via) passing through the electrical circuit board and a bottom surface pad, which thermally contacts the via and is provided on the bottom surface of the electrical circuit board, are installed directly below the surface pad, and the bottom surface pad contacts the heat sink, to which the electrical circuit board is attached, or the external electrical circuit board, the heat of the heaters disposed on the electrical circuit board may be finally discharged to the heat sink coupled with the electrical circuit board or the external electrical circuit board, and the driver circuit or the laser diode may be prevented from being damaged or degraded in functionality due to the heat.

Here, when the via is sufficiently wide, and a material of the via has sufficiently great thermal conductivity, the exposed upper end or the exposed lower end may play the role of the pad without necessarily forming the surface pad or the bottom surface pad.

Here, the via may play the role of electrical signal transmission as well as heat transfer like a typical via. Thus, the via may be used as the ground passage for improving the high speed signal characteristic in the entire circuit (here, the ground may refer to a broad concept including a general signal ground or an earth for preventing electrostatic shock), and the material of the via and the pads may include metal having excellent thermal and electrical conductivity.

The terminals of the electrical signal interface on the surface of the ECB are connected to some electrical terminals of the LD driver chip by print leading wires (conductive patterns 15) and bonding wires 17. Other electrical terminals of the LD driver chip 40 and other electrical terminals of the sub-mount 50 are connected by other bonding wires 19. Although not shown, the electrical terminals connect signals through direction contact with the terminals of the laser diodes 60 within the sub-mount 50.

Accordingly, when an electrical signal from another part connected to the interface surface of the electrical signal is received, the laser diode receives the electrical signal, generates a laser light signal, and transfers the laser light signal to an optical cable through a waveguide plate that is an external part. In contrast, in an embodiment of an optical receiver form, the optical signal of the optical cable may be inputted to the optical module of the present invention, and thus an electrical signal may be output to the electrical terminal of the external part connected to the electrical signal interface.

In an embodiment in which the ECB is not used, the mount itself at the bottom layer of FIG. 3 may be an insulator plane block that plays the role of a heat sink. Such a plane block may be a material of which various pads and signal connection patterns can be made, for example, silicon-series (Si), ceramics-series (Al2O3, AlN), silica-series (SiO2) or common PCB-series (Rogers, Tefron, FR-4, etc.).

In such a configuration of the present invention, the pad itself of the electrical digital signal interface and the electrical analog signal interface can be directly used as an interface with an external part, forming a structure for optimizing a small size, integration and performance of a high-speed signal line in the optical module (a sub-assembly for optical transmission/reception).

In the aforementioned embodiment, the sub-mount 50 has been disposed for the laser diodes. In some embodiments, however, a sub-mount for the LD drivers may be separately formed or may be integrated with the laser diodes. Such a form may also be different depending on a material that forms the mount and a function of the mount. For example, if the mount is chiefly made of synthetic resin (e.g., PCB), it is preferred that the two parts of an integration type sub-mount are thermally separated in order to prevent thermal transfer between the two parts. It is preferred that the mount 10 and the sub-mount 50 are thermally connected.

In another embodiment, however, if the mount is made of a substance (e.g., AlN or Si) having excellent thermal transfer, the mount itself may play the role of the sub-mount. In such a case, it may be difficult to separate the two parts. In such a case, however, thermal noise between the two parts can be minimized using an isolation structure, such as a trench.

The sub-mount for the driver and the sub-mount for the laser diode may be connected to the bottom through a via instead of a bonding wire. The reason for this is for adding a function for discharging internally generated heat to the outside using the via and the bottom. If the mount is basically made of synthetic resin, the via is preferred. If the mount is made of metal, ceramics or a silicon-series material, it may be preferred that the via is not use in terms of thermal transfer, the easy of fabrication and a production cost because the mount has excellent thermal conductivity.

An example of the external part or external factor connected to the mount may include high speed signal lines for transferring an external signal and control lines for controlling the laser diode or the photo sensor and monitoring performance.

If an electrical element is attached to the mount, an electrical circuit may be configured in the mount. For example, an electrical filter may be disposed in order to remove noise of a power signal inputted to the electrical element. Alternatively, in order to adjust a signal level, a circuit, such as an impedance matching circuit, may be configured.

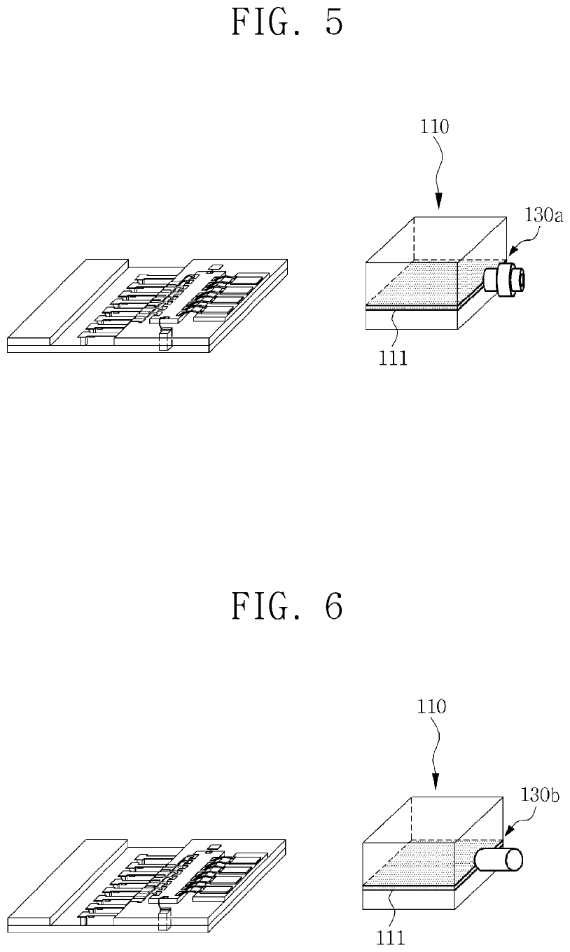

FIGS. 5 and 6 are optical modules described in the present invention in order to help understanding, and show an optic sub-assembly (OSA) and the waveguide plate 111 of a waveguide plate block 110, that is, an external part connected through the OSA, and an optical cable port. A coupling form is not limited to the above example, and those skilled in the art may readily understand any coupling form based on the contents described in the present invention.

FIG. 5 shows a case where an optical input/output unit is a receptacle 130a. If the waveguide plate block 110 operates as a multi-channel, the waveguide plate block 110 has a wavelength multiplexing/inverse multiplexing function because it includes one output port.

FIG. 6 shows a case where an optical input/output unit is a ferrule 130b. Likewise, if the waveguide plate block 110 operates as a multi-channel, the waveguide plate block 110 has a wavelength multiplexing/inverse multiplexing function because it includes one output port.

The optical interface of the optical input/output unit may be considered to be an MPO as in the above example. In this case, a method using a fiber block and using a fiber array is preferred.

The detailed embodiments of the present invention have been described in detail above, but those skilled in the art will evident understand that the present invention may be modified and changed in various ways within the scope of the technical spirit of the present invention and such medications and changes belong to the appended claims.

### DESCRIPTION OF REFERENCE NUMERALS

10: circuit board (mount)

11: base layer

13: cover layer

15: conductive pattern

17, 19: bonding wire

51: front groove

20: electrical digital signal interface

21, 31: electrical pad

23, 33: via

30: electrical analog signal interface

40: LD driver chip

50: sub-mount

53: groove

60: laser diode

70: optical signal interface

What is claimed is:

1. An optical module, comprising a mount, a laser diode (LD) driver and a sub-mount installed on the mount, a plurality of laser diodes disposed on the sub-mount, an electrical signal interface disposed on the mount, and a circuit connecting the electrical signal interface and signal input/output terminals of the LD driver and connecting the signal input/output terminals of the LD driver to the laser diodes through a terminal of the sub-mount, wherein:
a front of the laser diode is inward recessed at a specific distance from a front of the sub-mount and stepwise disposed with respect to the front of the sub-mount, and
a front groove which prevents hindrance to a travel (scattering, refraction and reflection) of laser light attributable to a portion comprising an edge of the sub-mount and adhesives in a direction in which the laser light emitted from the front of the laser diode travels and prevents a change in characteristics of a laser boundary surface is formed in a surface of the sub-mount.

2. The optical module of claim 1, wherein a concave groove or hole which prevents hindrance to a travel (scattering, refraction and reflection) of laser light attributable to the sub-mount and adhesives and prevents a change in the characteristics of the laser boundary surface is formed in the surface of the sub-mount in a periphery of a back of the laser diode.

3. The optical module of claim 2, wherein a photo sensor (or photo detector) which senses an intensity of backside light of the laser diode in a path in which the backside light of the laser diode travels is disposed in the groove or the hole.

4. The optical module of claim 3, wherein at least part of the photo sensor is buried in the groove or hole.

5. The optical module of claim 1, wherein the mount comprises an electrical circuit board (ECB) having an insulating property and capable of forming an electronic circuit in one or more planes.

6. The optical module of claim 5, wherein:
an interface surface of the electrical signal interface is a bottom of the ECB,
an electrical terminal (or pad) of the electrical signal interface is formed in a surface of the ECB,
the interface surface and the electrical terminal are connected through a via penetrating the ECB, and
the electrical terminal and signal input/output terminals of the LD driver chip are connected using at least one of a conductive pattern and bonding wire formed in the surface of the ECB.

7. The optical module of claim 6, wherein:
the electrical signal interface is divided into a digital signal interface and an analog signal interface,
a via of the digital signal interface comprises a via formed to penetrate a thin portion comprising a base layer of the ECB,
a via of the analog signal interface comprises a via formed in a thick portion having the base layer and cover layer of the ECB, and
the LD driver and the sub-mount are disposed in the thick portion of the ECB.

8. The optical module of claim 1, wherein:
an installation groove of a specific depth is formed in an area which belongs to the surface of the sub-mount and to which a bottom of the laser diode is attached, and
the front groove is formed from the installation groove to the front of the sub-mount.

9. The optical module of claim 1, wherein the mount comprises an electrical circuit board (ECB) having an insulation property, a surface pad is disposed on a surface of at least one layer of the mount, and at least one of heating elements including the sub-mount, on which the LD driver and the plurality of laser diodes are disposed, is disposed on the surface pad for thermal contact.

10. The optical module of claim 9, wherein a thermal via, which passes through the mount, is disposed below the surface pad in the mount, and a bottom surface pad, which is disposed on a bottom surface of the mount, is disposed below the via.

11. The optical module of claim 10, wherein the thermal via also plays the role of an electrical via, which is a passage for an electrical signal, and is made of a thermal and electrical conductor.

12. The optical module of claim 11, wherein the via is used as a ground for improving a high speed signal characteristic of the electrical circuit.

13. An optical module, comprising a mount, a laser diode (LD) driver and a sub-mount installed on the mount, a plurality of laser diodes disposed on the sub-mount, an electrical signal interface disposed on the mount, and a circuit connecting the electrical signal interface and signal input/output terminals of the LD driver and connecting the signal input/output terminals of the LD driver to the laser diodes through a terminal of the sub-mount, wherein:
a front of the laser diode is inward recessed at a specific distance from a front of the sub-mount and stepwise disposed with respect to the front of the sub-mount, and
laser light is emitted from a front of the laser diodes.
